(19) United States
(12) Patent Application Publication
(10) Pub. No.: US 2011/0214711 A1
(43) Pub. Date: Sep. 8, 2011

(54) SOLAR PANEL

(75) Inventors: Otto Hauser, Esslingen (DE); Hartmut Frey, Esslingen (DE)

(73) Assignee: Dritte Patentportfolio Beteiligungsgesellschaft mbH &Co. KG, Schoenefeld/Waltersdorf (DE)

(21) Appl. No.: 13/054,220

(22) PCT Filed: Jul. 9, 2009
(86) PCT No.: PCT/EP2009/058757

§ 371 Date: May 13, 2011

(30) Foreign Application Priority Data
Jul. 15, 2008 (DE) 10 2008 033 217.8

(51) Int. Cl. H01L 31/052

(52) U.S. Cl. 136/246

(57) ABSTRACT

A solar cell has a substrate made of a textile planar structure. The textile planar structure is assembled from light transparent glass-fiber threads and electrically conductive, but non-transparent carbon-fiber threads. The glass-fiber threads serve as spacers and fillers for the carbon-fiber threads, so that sufficiently light transparent, closed interstices are created between the carbon-fiber threads, whereby the light can pass through the substrate. Semiconductor layers, which form a blocking layer in-between, are located on both sides of the thus-formed substrate. One electrode is generated by the carbon-fiber threads of the substrate.

### CROSS-REFERENCE TO RELATED APPLICATIONS

This application is a Section 371 of International Application No. PCT/EP2009/058757, filed Jul. 9, 2009, which was published in the German language on Jan. 21, 2010, under

International Publication No. WO 2010/006988 A1 and the disclosure of which is incorporated herein by reference.

### BACKGROUND OF THE INVENTION

A solar panel consists of a substrate that is simultaneously a mechanical support for the semiconductor layers applied to this substrate. The semiconductor layers create a planar blocking layer on which free electrons are produced when irradiated. With external wiring of the solar panel, these free electrons generate a direct current.

The substrate that forms the mechanical support is not transparent in the known solar cells.

### BRIEF SUMMARY OF THE INVENTION

Starting from these conditions, the object of the invention is to create a solar cell/solar panel that distinguishes itself by an improved efficiency.

This object was achieved according to the invention with a solar panel or a solar cell comprising a substrate having two sides and side edges and being transparent and electrically conductive, a first doped semiconductor layer arranged on one side of the substrate, a second doped semiconductor layer arranged on the first semiconductor layer and forming a pn-junction with the first semiconductor layer, a third doped semiconductor layer arranged on the other side of the substrate and being of the same conductivity type as the first semiconductor layer, and a fourth doped semiconductor layer arranged on the third semiconductor layer and forming a pn-junction with the third semiconductor layer.

In the solar cell according to the invention, the mechanically rigid substrate is made of a light transparent and electrically conductive material. A pair of semiconductor layers is applied to each of the flat sides of the substrate. The two semiconductor layers from each pair of semiconductor layers, which are directly adjacent to the substrate, are of the same conductivity type. At the boundary layer between the semiconductor layers of each pair, a blocking layer is created, which outputs electrons when irradiated with light.

Because the substrate is light transparent, photons that were not absorbed when striking the first blocking layer can enter through the light transparent support into the second blocking layer and are possibly drawn in there, in turn, for generating free electrons.

Thus, in the solar cell according to the invention, two blocking layers are available on both sides of the substrate or support, which significantly increases the efficiency.

The substrate can have a lattice or lattice-like structure.

The substrate can be formed from a textile planar structure, with the result that the substrate is very lightweight and flexible and is thus less susceptible to breakage, although it is very thin.

In the case of a substrate based on a textile planar structure, this can contain a mixture made of light transparent threads and non-transparent, electrically conductive fibers or threads.

In the case of light transparent threads, these are advantageously threads made from glass fibers.

The threads made from electrically conductive material can be metallic threads or carbon-fiber threads.

Due to the connection between light transparent and electrically conductive threads or fibers, it is achieved that the electrons can flow out of the blocking layer formed by the support or the substrate. The support or substrate acts in this respect as an electrode, wherein the light transparent threads between the predominantly non-transparent threads provide for the necessary “holes” through which the light may pass to the rear layer, i.e., the blocking layer away from the light source.

In each case, the obtained substrate is very flexible and comparatively extremely lightweight and thin.

The substrate or the carrier can be present in the form of a woven fabric, a knitted fabric, or a knotted fabric. In the case of a woven fabric with a linen or twill weave, the warp threads are made of glass-fiber threads and the woof threads are made of carbon-fiber threads. The reverse arrangement is likewise conceivable, in which the material for the warp and the woof threads are exchanged with each other, depending on which can be more easily woven.

In the case of a knitted or knotted fabric, the stitch rows can be made alternately of glass-fiber threads or carbon-fiber threads.

A light transparent, electrically conductive layer, which is preferably made of ZnO, can be applied on each outer semiconductor layer.

For contacting, an aluminum lattice can be used, which is applied, for example, with the help of a pad printing method.

In order to improve the efficiency, at least one outer surface is provided with an anti- reflective layer.

The scratch sensitivity is improved when the outer layer is a C-layer in a diamond structure.

### BRIEF DESCRIPTION OF THE SEVERAL VIEWS OF THE DRAWINGS

The following description of the figures explains aspects for understanding the invention. From the drawing, one skilled in the art can, in the customary way, take further non- described details, which supplement the description of the figures in this respect. It is clear that a range of modifications are possible; the exact dimensioning can be performed easily by one skilled in the art empirically on the basis of the specified data.

The following figures are not to scale. For the illustration of details, certain regions are shown disproportionately large. In addition, the figures are strikingly simplified and do not contain every optional detail present in the practical embodiment.

In the drawings, an embodiment of the subject of the invention is shown:

FIG. 1 is a schematic, longitudinal sectional view through a segment of a solar cell according to an embodiment of the invention; and

FIG. 2 is a schematic, perspective view of a knitted fabric and how it can be used as the substrate for the solar element according to an embodiment of the invention.

### DETAILED DESCRIPTION OF THE INVENTION

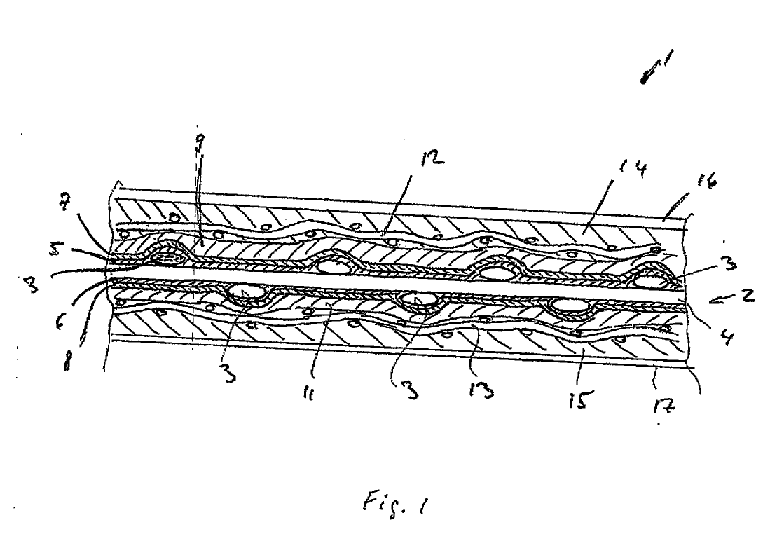

FIG. 1 shows a strongly schematized, strikingly simplified section through a solar cell 1. A substrate 2, in the form of a woven fabric with a linen or twill weave, belongs to the solar cell 1.

The woven fabric forming the substrate 2 has warp threads 3 and also woof threads 4. This type of woven fabric is known from the textile technology and does not need to be described or illustrated further. As indicated on the left side, the warp threads 3 consist of a plurality of glass-fiber monofilaments lying parallel next to one another and optionally also twisted with each other. They are thus light transparent, but not electrically conductive.

The woof threads 4 are, in contrast, made of carbon fibers and are thus electrically conductive.

It is understood that the warp and woof threads could also exchange places, that is, the threads designated with 4 could also be warp threads, while the threads designated with 3 would then be woof threads. This is not important for further consideration.

A p-doped Si layer 5 is located, with reference to FIG. 1, on the top side on the thus- formed substrate 2 in the form of a textile planar structure. Another p-doped Si layer 6 is applied on the bottom side of the substrate 2. An n-doped Si layer 7 is located on the surface of the Si layer 5 facing away from the substrate 2, and another n-doped Si layer 8 is present on the Si layer 6 on the side facing away from the substrate 2.

The Si layers 5 and 7 form a semiconductor pn-junction just like the two layers 6 and 8 at their contact face. This blocking layer is the actual active part of the solar cell 1.

A layer 9 with good electrical conductivity, for example made of ZnO, is applied on the free side of the Si layer 7, that is, the side facing away from the substrate 2. This zinc-oxide layer serves for reducing the internal resistance. A corresponding zinc-oxide layer 11 is located on the Si layer 8 and, indeed, on the side opposite the Si layer.

For the purpose of contacting the two ZnO layers 9 and 11, two aluminum lattice structures 12 and 13 are provided, which are shown symbolically in FIG. 1 as wire mesh. These lattice structures 12 and 13 represent electrodes for contacting the Si layers 7 and 8.

The lattice structures 12 and 13 are illustrated with the cross section as shown merely for the purpose of recognizability. Actually, the lattices involve lattice structures, which are printed in a pad printing method. Such a structure would not be recognizable in the diagram; the selected wire structure is here shown as a representative. The application of such lattice structures is sufficiently known from the prior art.

So that incident light is reflected as little as possible, anti-reflective layers 14 and 15 made of Si₃N₄ are located on the outside of the ZnO layer 9 and on the outside of the ZnO layer 11, respectively. Finally, on the outsides of each of the anti-reflective layers 14 and 15, protective layers 16 and 17, respectively, are applied as mechanical protection. Layers 16 and 17 involve carbon layers in a diamond structure. Such layers are generated using CVD processing (Chemical Vapor Deposition).

The Si layers 5, 6, 7, and 8 can likewise be generated using CVD processing or in a way and manner as described in detail in DE 10 2007 50 288.

For the purpose of contacting planar silicon photodiodes generated in this way, the lattice structure 12 or 13 is connected at the edge of the solar cell to corresponding copper conductors. For this purpose, the lattice structures 12, 13 project with corresponding lengths at the side edge or the edges of the solar cell 1.

The second electrodes form the threads 4 that consist of carbon fibers and run in parallel next to one another due to the fabric weave. The carbon fibers likewise project laterally from the solar cell 1 and are provided in a suitable way with a metal layer on the projecting end, in order here to generate good contacting to metallic conductors.

The functioning of the described solar cell 1 is as follows:

When, for example with reference to FIG. 1, light coming from above is incident on the solar cell 1, this light succeeds through the protective layer 16, the anti-reflective layer 14, the lattice structure 12, and the contacting layer 9 into the blocking layer formed between the two Si layers 5 and 7. The incident photons hereby generate electrons that can flow via the electrodes 4 and 12 to a load and can succeed back to the other side of the blocking layer after flowing through the load.

Because not all of the photons of the incident light generate free electrons, but instead pass undisturbed through the blocking layer between the Si layers 5 and 7, they are succeed through the lattice structure of the substrate 2 into the blocking layer between the Si layers 6 and 8. Thus, photons not consumed in the upper blocking layer can likewise be drawn into the second blocking layer for generating free electrons.

Based on the details of the function, one skilled in the art is in the position to realize the dimensioning of the substrate 2. A favorable compromise for each application must be made between the number of conductive carbon fibers 4 and the non-conductive, but light transparent glass threads 3. If the distance between the carbon-fiber threads 4 becomes too large, then the internal resistance of the solar cell 1 increases. In contrast, if the distance is selected too small, then the blocking layer lying away from the light source and in this respect lying on the reverse side of the substrate 2 receives too little irradiation.

As is likewise given from the description of the function, the glass-fiber threads 3, which are woven with the carbon-fiber threads 4, act as spacers for the carbon-fiber threads. A flexible substrate that is, on one hand, light transparent and, on the other hand, electrically conductive and sufficiently rigid is created, so that when the substrate is loaded mechanically, the applied layers cannot become damaged to the extent that the solar cell becomes non-functional. Fractures and cracks in the Si layers 5 . . . 8 ultimately do not negatively affect the functionality of the solar cell 1, because the islands created by the fractures are connected to each other electrically in parallel by the electrodes in the form of the lattice structure 12, 13, as well as the carbon-fiber threads 4.

The structure is illustrated in FIG. 1 to be symmetric with respect to the substrate 2. It is understood, however, that the anti-reflective layer 15, for example, could also be eliminated in the reverse side.

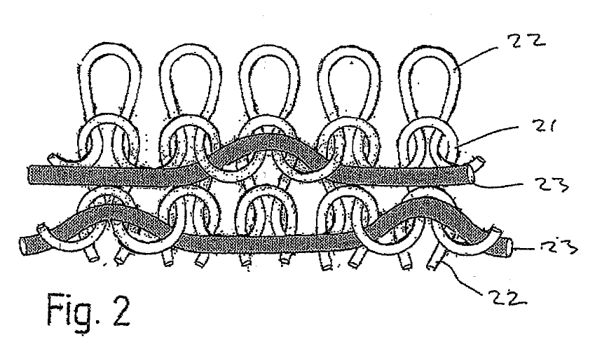

Not only the woven fabric indicated schematically in FIG. 1, but also a knitted fabric as FIG. 2 shows, is suitable as substrate 2. In the knitted fabric according to FIG. 2, stitch rows 21 alternate with stitch rows 22 in the knitted fabric, with these rows consisting alternately of glass- fiber threads and carbon-fiber threads. Another possibility consists in, for example, manufacturing two stitch rows, which are directly adjacent to each other, from glass-fiber threads and every third stitch row from carbon-fiber threads.

In the knitted fabric, the glass-fiber threads act, in turn, as spacers for the carbon-fiber threads, so that the light passage through the substrate to the blocking layer lying on the reverse side from the point of view of the light source is not blocked.

There is no need for further explanation that the knitted fabric must be manufactured in a correspondingly tight manner and may not contain “holes” in the stitches; in this respect, the figure does not accurately reproduce the practical solution, because the stitches enclose clear openings for reasons of illustration.

If the elasticity of the knitted fabric is undesirably large, floating threads 23 could be used, as shown, in the stitch rows. These floating threads could comprise glass-fiber threads or carbon-fiber threads. If the floating threads are carbon-fiber threads, then the stitch rows could be knitted exclusively from glass-fiber threads, which offers advantages with respect to the ease of knitting. Expediently, as the substrate, simple right-to-left knitting is used, which can be produced in an especially thin way.

A solar cell has a substrate made of a textile planar structure. The textile planar structure is assembled from light transparent glass-fiber threads and electrically conductive, but non-transparent carbon-fiber threads. The glass-fiber threads serve as spacers and fillers for the carbon-fiber threads, so that sufficiently light transparent, closed interstices are created between the carbon-fiber threads, whereby the light can penetrate through the substrate. Semiconductor layers, which form a blocking layer in-between, are located on both sides of the thus-formed substrate. One electrode is generated by the carbon-fiber threads of the substrate.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1-14. (canceled)

15. A solar panel (1) comprising:
a substrate (2) having first and second major sides and side edges and being transparent and electrically conductive,
a first doped semiconductor layer (5) arranged on the first major side of the substrate (2),
a second doped semiconductor layer (7) arranged on the first doped semiconductor layer (5) and forming a pn-junction with the first doped semiconductor layer (5),
a third doped semiconductor layer (6) arranged on the second major side of the substrate (2) and being of a same conductivity type as the first doped semiconductor layer (5), and
a fourth doped semiconductor layer (8) arranged on the third doped semiconductor layer (6) and forming a pn-junction with the third doped semiconductor layer (6),
wherein the substrate (2) comprises a woven fabric, a knitted fabric or a knotted fabric.

16. The solar panel according to claim 15, wherein the substrate (2) has a lattice structure.

17. The solar panel according to claim 15, wherein substrate (2) comprises a textile planar structure.

18. The solar panel according to claim 15, wherein the substrate (2) contains first threads (3) made of light transparent material.

19. The solar panel according to claim 18, wherein the first threads (3) comprise glass-fiber threads.

20. The solar panel according to claim 15, wherein the substrate (2) contains second threads (4) made of electrically conductive material.

21. The solar panel according to claim 20, wherein the electrically conductive material is selected from carbon fibers and metals.

22. The solar panel according to claim 21, wherein the electrically conductive material comprises copper.

23. The solar panel according to claim 15, wherein the substrate (2) comprises a woven fabric in linen weave or twill weave.

24. The solar panel according to claim 23, wherein the woven fabric (2) comprises warp threads (3) made of transparent material and woof threads (4) made of electrically conductive material.

25. The solar panel according to claim 23, wherein the woven fabric (2) comprises warp threads (3) made of electrically conductive material and woof threads (4) made of transparent material.

26. The solar panel according to claim 15, wherein the substrate (2) comprises a knitted or knotted fabric, wherein rows (21, 22) made of light transparent material alternate with rows (21, 22) made of electrically conductive material.

27. The solar panel according to claim 15, wherein a light transparent, electrically conductive layer (9, 11) is applied on each of the second and fourth semiconductor layers (7, 8).

28. The solar panel according to claim 27, wherein the light transparent, electrically conductive layer (9, 11) comprises ZnO.

29. The solar panel according to claim 15, further comprising a lattice (12, 13) made of electrically conductive material as an external electrode for each of the second and fourth semiconductor layers (7, 8).

30. The solar panel according to claim 29, wherein the lattice (12, 13) made of electrically conductive material comprises aluminum.

31. The solar panel according to claim 15, further comprising an anti- reflective layer (14, 15) on one side.

32. The solar panel according to claim 31, wherein the anti-reflective layer (14, 15) comprises Si₃N₄.

33. The solar panel according to claim 15, further comprising at least on one side a protective layer (16, 17) having a diamond structure.
